(19) United States
(12) Patent Application Publication
(10) Pub. No.: US 2014/0184039 A1
(43) Pub. Date: Jul. 3, 2014

(54) DEVICE HOUSING AND METHOD FOR MANUFACTURING THE SAME

(71) Applicants: FIH (Hong Kong) Limited, Kowloon (HK); SHENZHEN FUTAIHONG PRECISION INDUSTRY CO., LTD., Shenzhen (CN)

(72) Inventor: REN-BO WANG, Shenzhen (CN)

(21) Appl. No.: 13/930,306

(22) Filed: Jun. 28, 2013

(30) Foreign Application Priority Data
Dec. 29, 2012 (CN) 2012105902703

(51) Int. Cl. H05K 5/02; B29C 71/02

(52) U.S. Cl. CPC H05K 5/02; B29C 71/02
USPC 312/223.1; 264/645

(57) ABSTRACT

A device housing providing a sensation of touch similar to that of jade is made of a material including quartz, clay mineral and a polymer composition containing calcium-magnesium. The clay mineral includes elemental Zn, aluminum oxide, calcium oxide, magnesium oxide, barium oxide, silicon oxide, and titanium oxide. The polymer composition containing calcium-magnesium comprises iron (III) oxide, iron (II, III) oxide, calcium carbonate, and calcium silicate. A method for manufacturing the device housing is also provided.

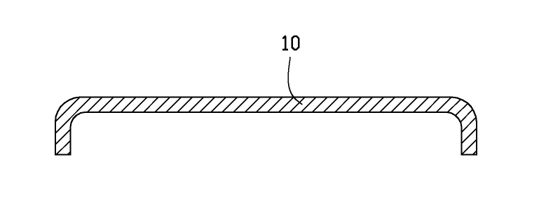

### BACKGROUND

1. Technical Field

The exemplary disclosure generally relates to a device housing and a method for manufacturing the device housing.

2. Description of Related Art

Metal, plastic and glass are widely used to form housings of electronic devices. However, these common housing materials have disadvantages such as low erosion resistance and fragility and cannot provide the smoothness and tactile sensations that jade can.

Therefore, there is room for improvement within the art.

### BRIEF DESCRIPTION OF THE FIGURES

Many aspects of the device housing can be better understood with reference to the following FIGURE. The components in the figures are not necessarily drawn to scale, the emphasis instead being placed upon clearly illustrating the principles of the device housing.

The FIGURE is a cross-section of a device housing according to an exemplary embodiment.

### DETAILED DESCRIPTION

The FIGURE shows a device housing 10 according to an exemplary embodiment. The device housing 10 may be a housing of a mobile phone, a personal digital assistant, a notebook computer, an MP3 player, a GPS navigator, a bluetooth headset, a digital camera, a sound box, etc.

The device housing 10 is made of a material substantially comprising quartz, clay mineral, and a polymer composition containing calcium-magnesium. The device housing 10 further contains a doping agent such as carbide, nickel oxide, and lead oxide. In the device housing 10, the mass percentage of the quartz is about 51% to about 62%, the mass percentage of the clay mineral is about 27% to about 34%, the mass percentage of the polymer composition containing calcium-magnesium is about 8% to about 10%, and the mass percentage of the doping agent is about 3% to about 5%.

The clay mineral contains kaolinite, montmorillonite, calcite, mica, and/or illite.

The clay mineral contains elemental zinc (Zn) and oxides such as aluminum oxide (Al₂O₃), calcium oxide (CaO), magnesium oxide (MgO), barium oxide (Ba₂O₃), silicon oxide (SiO₂), and titanium oxide (TiO₂). The polymer composition containing calcium-magnesium contains iron (III) oxide (Fe₂O₃), iron (II, III) oxide (Fe₃O₄), calcium carbonate (CaCO₃), and calcium silicate (CaSiO₄).

A method for manufacturing the device housing 10 may include the following steps:

(1) The material for making the device housing 10 is provided. The material is in powder form and has a grain size of about 0.4 mm to about 0.1 mm.

(2) A molding feedstock is provided.

The material, a binder, and a plasticizer are mixed together to produce a mixture. In the mixture, the volume ratio of the material, binder, and plasticizer is about (42-47): (35-50):(3-8). The mixture is agitated in a mixer (not shown) at a temperature of about 140 degrees Celsius (° C.) to 180° C. for about 60 min to about 150 min to produce a cylindrical molding feedstock. The binder includes polyethylene (PE) and polypropylene (PP). The plasticizer is dibutylphthalate (DBP). The length of the molding feedstock is about 4 mm to 7 mm. The diameter of the molding feedstock is about 2 mm to 3 mm.

(3) A green body is formed by powder injection molding.

A mold (not shown) is provided. The molding feedstock is heated to about 150° C.-170° C. and then injected into the mold under a pressure of about 120 MPa to about 180 MPa. After the injection process, the mold is maintained at a pressure of about 200 MPa to about 300 MPa for about 20 min to about 50 min.

(4) The green body is heated to degrease.

The green body is positioned in a degreasing furnace (not shown). The internal temperature of the degreasing furnace is heated to about 850° C. by the following steps: first, the internal temperature of the furnace is heated to about 150° C. at a rate of about 25° C./h to about 37° C./h; second, the internal temperature of the degreasing furnace is heated to about 400° C. at a rate of about 3.8° C./h to about 6.3° C./h; third, the internal temperature of the degreasing furnace is heated to about 500° C. at a rate of about 6.6° C./h to about 10° C./h; fourth, the internal temperature of the degreasing furnace is heated to about 850° C. at a rate of about 29.2° C./h to about 50° C./h. During the degreasing process, the binder and the plasticizer contained in the green body are melted, decomposed and removed. After the degreasing process, the green body is naturally cooled to room temperature.

(5) The green body is sintered.

The green body is positioned in a sintering furnace (not shown). The interior of the sintering furnace is heated to about 1250° C. by the following steps: first, the internal temperature of the sintering furnace is heated to about 600° C. at a rate of about 4° C./h to about 6° C./h; second, the internal temperature of the sintering furnace is heated to about 800° C. at a rate of about 2° C./h to about 4° C./h; third, the internal temperature of the sintering furnace is heated to about 1250° C. at a rate of about 0.8° C./h to about 1.2° C./h.

After that, the internal temperature of the sintering furnace is cooled to room temperature at a rate of about 3.7° C./h to about 6° C./h.

(6) The green body is milled by a computer numerical control or cut by laser beam to produce the device housing 10 with a desired shape.

(7) The device housing 10 is ground or polished.

(8) The device housing 10 is cleaned by the following steps: first, the device housing 10 is washed with a weak acid solution having a pH value of about 5 for about 5 min to 15 min to remove any alkaline doping agent on the surface; second, the device housing 10 is washed with a weak alkali solution having a pH of about 9 for about 5 min to 15 min to remove any acid doping agent on the surface; third, the device housing 10 is washed with an alcohol or acetone for about 5 min to 15 min to remove any organic doping agent on the surface; fourth, the device housing 10 is washed with pure water and then dried at a temperature of about 60° C.-80° C. for about 40 min to about 80 min. In the embodiment, the weak acid is a hydrochloric acid solution, and the weak alkali is a sodium hydroxide solution.

The device housing 10 manufactured by this method provides users with the same tactile sensations as given by jade. Further, the device housing 10 has excellent corrosion resistance and aging resistance. In addition, the device housing 10 can form any three-dimensional structure easily since it is formed by molding.

It is to be understood, however, that even though numerous characteristics and advantages of the exemplary disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A device housing:
the device housing being made of material substantially comprising quartz, clay mineral, and polymer composition containing calcium-magnesium, the clay mineral comprising elemental zinc, aluminum oxide, calcium oxide, magnesium oxide, barium oxide, silicon oxide, and titanium oxide, the polymer composition containing calcium-magnesium comprising iron (III) oxide, iron (II, III) oxide, calcium carbonate, and calcium silicate.

2. The device housing of claim 1, wherein in the device housing, the mass percentage of the quartz is about 51% to about 62%, the mass percentage of the clay mineral is about 27% to about 34%, and the mass percentage of the polymer composition containing calcium-magnesium is about 8% to about 10%.

3. The device housing of claim 1, further comprising doping agent comprised of carbide, nickel oxide, and lead oxide.

4. The device housing of claim 3, wherein the mass percentage of the doping agent is about 3% to about 5% in the device housing.

5. The device housing of claim 1, wherein the clay mineral comprises kaolinite, montmorillonite, calcite, mica, and/or illite.

6. A method for manufacturing a device housing comprising:
providing a material substantially comprising quartz, clay mineral and polymer composition containing calcium-magnesium, the clay mineral comprising elemental zinc, aluminum oxide, calcium oxide, magnesium oxide, barium oxide, silicon oxide, and titanium oxide, the polymer composition containing calcium-magnesium comprising iron (III) oxide, iron (II, III) oxide, calcium carbonate, and calcium silicate;
mixing the material, a binder, and a plasticizer together to produce a mixture, and agitating the mixture in a mixer to produce a molding feedstock, the binder comprising polythene and polypropylene, the plasticizer being dibutylphthalate;
injecting the molding feedstock into a mold to produce a green body by powder injection molding;
degreasing the green body; and
sintering the green body.

7. The method of claim 6, wherein in the mixture, the volume ratio of the material, the binder and the plasticizer is about (42-47):(35-50):(3-8).

8. The method of claim 7, wherein the molding feedstock is produced by the mixer at a temperature of about 140° C. to about 180° C. for about 60 min to about 150 min.

9. The method of claim 7, wherein the molding feedstock has a cylindrically-shaped structure.

10. The method of claim 9, wherein the length of the molding feedstock is about 4 mm to about 7 mm.

11. The method of claim 9, wherein the diameter of the molding feedstock is about 2 mm to about 3 mm.

12. The method of claim 6, wherein the green body is degreased within a degreasing furnace by the following steps: first, the internal temperature of the degreasing furnace is heated to about 150° C. at a rate of about 25° C./h to about 37° C./h; second, the internal temperature of the degreasing furnace is heated to about 400° C. at a rate of about 3.8° C./h to about 6.3° C./h; third, the internal temperature of the degreasing furnace is heated to about 500° C. at a rate of about 6.6° C./h to about 10° C./h; fourth, the internal temperature of the degreasing furnace is heated to about 850° C. at a rate of about 29.2° C./h to about 50° C./h.

13. The method of claim 6, wherein during the sintering process, the green body is positioned in a sintering furnace, the interior of the sintering furnace is heated to about 1250° C. by the following steps: first, the internal temperature of the sintering furnace is heated to about 600° C. at a rate of about 4° C./h to about 6° C./h; second, the internal temperature of the sintering furnace is heated to about 800° C. at a rate of about 2° C./h to about 4° C./h; third, the internal temperature of the sintering furnace is heated to about 1250° C. at a rate of about 0.8° C./h to about 1.2° C./h.

14. The method of claim 13, wherein after the sintering furnace is heated to about 1250° C. the internal temperature of the sintering furnace is cooled to room temperature at a rate of about 3.7° C./h to about 6° C./h.

15. The method of claim 6, wherein during the injecting process, the molding feedstock is heated to about 150° C.-170° C., and then injected into the mold under a pressure of about 120 MPa to about 180 MPa.

16. The method of claim 15, wherein after the molding feedstock is injected into the mold, the mold is maintained at a pressure of about 200 MPa-300 MPa for about 20 min to about 50 min.
